(19) United States
(12) Patent Application Publication
(10) Pub. No.: US 2026/0113008 A1
(43) Pub. Date: Apr. 23, 2026

(54) Amplifier Having Multiple Current Paths

(71) Applicant: TEXAS INSTRUMENTS INCORPORATED, Dallas, TX (US)

(72) Inventor: Nimish Sehgal, Bangalore (IN)

(21) Appl. No.: 18/924,852

(22) Filed: Oct. 23, 2024

(51) Int. Cl. H03F 3/45

(52) U.S. Cl. CPC H03F 3/45269; H03F 2200/129

(57) ABSTRACT

An amplifier includes a mechanism to reduce kickback voltage during power up and powered down scenarios. The kickback mechanism may include a capacitor that is configured to couple a charge to a gate of an auxiliary transistor. The gate of the auxiliary transistor is shorted to a gate of a reference-controlled transistor of the amplifier. The capacitor at the gate of the auxiliary transistor is configured to couple a voltage to the gate of the auxiliary transistor, where that coupled voltage is complementary to a voltage that is capacitively coupled to the gate of the reference-controlled transistor. The complementarity of the voltages reduces or cancels the kickback voltage.

### TECHNICAL FIELD

The present disclosure relates generally to circuits and, more specifically, to an amplifier having multiple current paths.

### BACKGROUND

Some systems may include a multitude of devices, which are configured to receive a reference voltage from a same reference voltage source. For instance, a reference voltage source may provide a same reference voltage over a shared line to multiple different components that use the reference voltage. The various components may be designed to operate on an assumption that the reference voltage is stable.

### SUMMARY

In accordance to an embodiment, a circuit includes: an amplifier having an enable input terminal configured to receive a first enable signal, and a first transistor having a current path coupled between first and second supply terminals, and a control terminal coupled to a reference terminal; a second transistor having a current path coupled between the first and second supply terminals, and a control terminal coupled to the reference terminal; a third transistor having a current path coupled between the control terminal of the second transistor and the second supply terminal, and a control terminal configured to receive a second enable signal; and a first capacitor coupled between the control terminal of the second transistor and the current path of the third transistor.

In accordance to an embodiment, an integrated circuit (IC) includes: a bandgap reference circuit configured to generate a reference voltage at a reference voltage output; an amplifier having a reference input coupled to the reference voltage output and an inverting input coupled to a feedback path, where the amplifier further includes: a first current path having a first transistor having a current path disposed in series between first and second supply terminals, where a control terminal of the first transistor is coupled to the reference voltage output; a second current path having a second transistor having a current path disposed in series between the first and second supply terminals, where a control terminal of the second transistor is coupled to the reference voltage output and to the control terminal of the first transistor, and where the control terminal of the second transistor is coupled to the second supply terminal via a capacitor; and a third transistor having a current path coupled between the current path of the second transistor and the second supply terminal, and a control terminal configured to receive a first enable signal.

In accordance to an embodiment, a method includes: receiving a reference voltage with a control terminal of a first transistor of an amplifier, the first transistor having a current path coupled between first and second supply terminals; receiving the reference voltage with a control terminal of a second transistor of an auxiliary circuit, the second transistor having a current path coupled between the first and second supply terminals; receiving a first enable signal with a control terminal of a third transistor of the amplifier, the third transistor having a current path coupled to the current path of the first transistor; receiving a second enable signal with a control terminal of a fourth transistor of the auxiliary circuit, the fourth transistor having a current path coupled between the current path of the second transistor and the second supply terminal, where the second enable signal is an inverted version of the first enable signal; in response to an assertion of the first enable signal: causing a first source voltage at the first transistor to decrease; and causing a second source voltage at the second transistor to increase.

In accordance to an embodiment, an integrated circuit (IC) includes a first circuit including: first and second supply terminals; an output terminal; a reference terminal; a first transistor having a current path coupled between the first and second supply terminals, and a control terminal coupled to the reference terminal; a second transistor having a current path coupled between the first and second supply terminals and a control terminal coupled to the reference terminal; a third transistor having a current path coupled between the current path of the second transistor and the second supply terminal; a first capacitor coupled between the control terminal of the second transistor and the current path of the third transistor; a second capacitor coupled between the first capacitor and the second supply terminal; a fourth transistor having a current path coupled between the current path of the first transistor and the second supply terminal; a fifth transistor having a current path coupled between the output terminal and the second supply terminal, and a control terminal coupled to a control terminal of the fourth transistor; a sixth transistor having a current path coupled between the first supply terminal and the output terminal, and a control terminal coupled to the current path of the first transistor; a seventh transistor having a current path coupled between the first supply terminal and the current path of the first transistor; an eighth transistor having a control terminal coupled to a control terminal of the seventh transistor; and a ninth transistor having a control terminal coupled to the output terminal, and a current path terminal coupled between a current path of the eighth transistor and a current path of the fourth transistor.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is an illustration of an example integrated circuit (IC), according to some embodiments;

FIG. 2 is an illustration of an example amplifier, adapted according to some embodiments;

FIG. 3 is an illustration of voltages in the example amplifier of FIG. 2, according to some embodiments;

FIG. 4 is an illustration of an example LDO voltage regulator, according to some embodiments;

FIG. 5 is an illustration of an example amplifier, according to some embodiments; and

FIG. 6 is an illustration of an example method, according to some embodiments.

Corresponding numerals and symbols in different figures generally refer to corresponding parts unless otherwise indicated. The figures are drawn to clearly illustrate the relevant aspects of the preferred embodiments and are not necessarily drawn to scale.

### DETAILED DESCRIPTION

The present disclosure is described with reference to the attached figures. The figures are not drawn to scale, and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

The description below illustrates various specific details to provide an in-depth understanding of several example embodiments according to the description. The embodiments may be obtained without one or more of the specific details, or with other methods, components, materials and the like. In other cases, known structures, materials or operations are not shown or described in detail so as not to obscure the different aspects of the embodiments. References to “an embodiment” in this description indicate that a particular configuration, structure or feature described in relation to the embodiment is included in at least one embodiment. Consequently, phrases such as “in one embodiment” that may appear at different points of the present description do not necessarily refer exactly to the same embodiment. Furthermore, specific formations, structures or features may be combined in any appropriate manner in one or more embodiments.

Various embodiments may include an auxiliary current path within an amplifier as a charge compensation mechanism to reduce or eliminate kickback at a reference voltage line received as an input by the amplifier. In one example, an amplifier receives a reference voltage from a shared reference voltage line. Other components may also receive the same reference voltage from the shared reference voltage line.

As the amplifier turns on or turns off, capacitive coupling between a source and a gate and a drain and the gate of a reference-controlled transistor may cause a kickback voltage on the shared reference voltage line received by the amplifier. The kickback voltage may appear as a short-duration spike on the shared reference voltage line, and it has the potential to disturb operation of other components that are coupled to receive the shared reference voltage line.

As noted above, the kickback may be caused by charge that is capacitively coupled from source to gate and from drain to gate of the reference-controlled transistor. Various embodiments reduce or eliminate the kickback by compensating the charge that is capacitively coupled at the reference-controlled transistor. For instance, the auxiliary current path may include an auxiliary transistor, which is gate coupled to the reference-controlled transistor and to the shared reference voltage line. The auxiliary current path may include capacitors coupled to the gate of the auxiliary transistor, and those capacitors may be charged and discharged to cause opposite charge coupling at the gates of the reference-controlled transistor and auxiliary transistor (the shared reference voltage line). The auxiliary transistor may be selected to have a threshold voltage that is the same as or similar to the threshold voltage of the reference-controlled transistor, thereby advantageously enabling same-sized and opposite charge coupling. For instance, a same length dimension shared between the auxiliary transistor and the reference-controlled transistor may allow for a same or similar threshold voltage.

The auxiliary current path may be implemented in any appropriate amplifier architecture, such as a five-pack structure followed by a pass transistor or other appropriate amplifier architecture. Furthermore, the amplifier having an auxiliary current path may be implemented within any of a variety of different components, such as a low dropout (LDO) voltage regulator, a buffer, or the like.

Various embodiments may have advantages over other systems. For instance, the auxiliary current path when implemented in an amplifier may advantageously reduce or eliminate kickback on a shared reference voltage line. That may allow the amplifier to coexist with other components that are coupled to the shared reference voltage line by reducing an amount of kickback attributable to the amplifier. Reduced kickback may advantageously improve operation of components that may be sensitive to fluctuations, even small fluctuations, of the reference voltage. Some embodiments may advantageously avoid implementation of additional circuits aimed at suppressing noise in the shared reference line (e.g., for sensitive circuits), which may advantageously save area.

Furthermore, since various embodiments may allow an amplifier to share a reference voltage line with other components, that may allow for increased sharing of the reference voltage line. Increased sharing of the reference voltage line may allow for a reduced number of reference voltage circuits, which may further save semiconductor area.

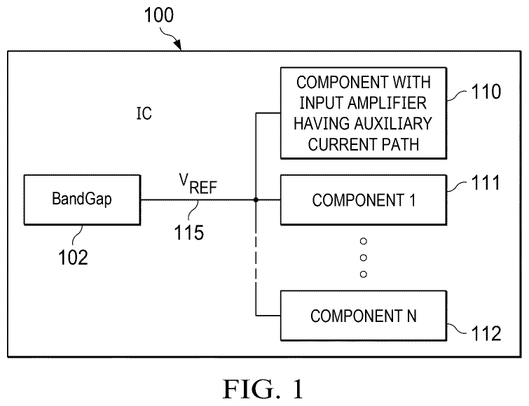

FIG. 1 is an illustration of an example integrated circuit (IC) 100, according to some embodiments. For instance, the various components 102 and 110-112 may be implemented on a single semiconductor die and included within a semiconductor package. In another example, one or more of the various components 102 and 110-112 may be implemented on separate or different semiconductor dies. The scope of implementations may include any arrangement of semiconductor dies and semiconductor packages. The ellipses between component 111 and component 112 indicates that components 111-112 represent N components, where N is a positive integer. The number of components may be scaled as appropriate for a given use case.

IC 100 includes bandgap reference generator 102. Bandgap reference generator 102 has a reference voltage output that is coupled to the component 110-112 by shared reference voltage line 115. Bandgap reference generator 102 provides a reference voltage VREF at its reference voltage output, via shared reference voltage line 115, to the component 110-112. Each of the components 110-112 may use the reference voltage VREF for various internal functions. Examples of components 111-112 may include an analog-to-digital converter (ADC), an LDO voltage regulator, a buffer, a phase locked loop (PLL) and/or any other appropriate component that may employ a reference voltage.

Further in this example, component 110 includes an input amplifier having an auxiliary current path. Examples of components that may have an input amplifier include buffers, LDOs, and the like. The auxiliary current path in the input amplifier of component 110 may function as a charge compensation device to, e.g., advantageously reduce kickback that may otherwise appear on the shared reference voltage line 115. By contrast, in an example in which kickback may be seen on the shared reference voltage line 115, the kickback may affect the operation of other ones of the components 110-112, which are coupled to the shared reference voltage line.

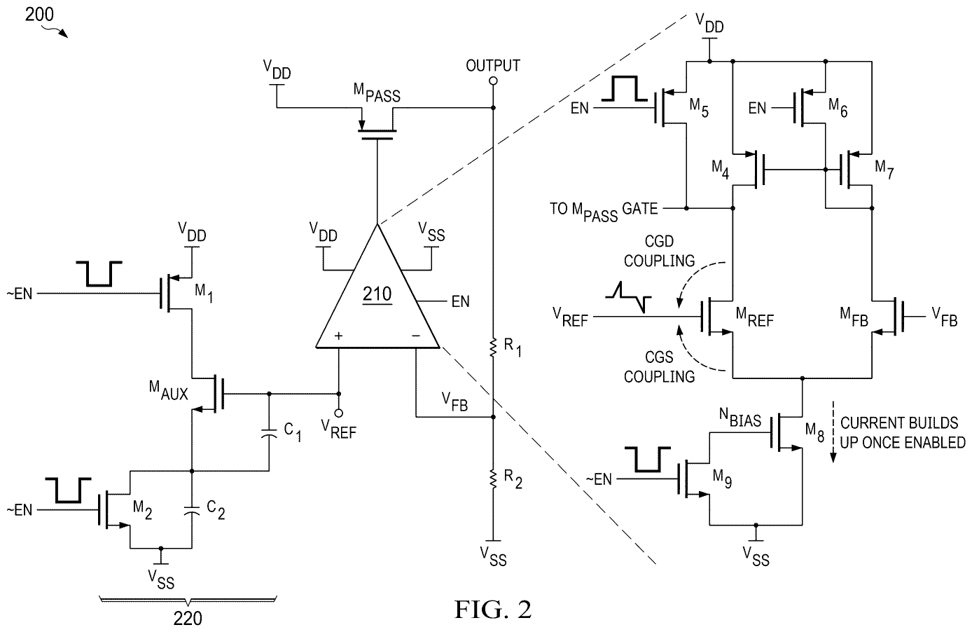

FIG. 2 is an illustration of an example amplifier 200, adapted according to some embodiments. Amplifier 200 includes operational amplifier (op amp) 210 and auxiliary current path 220.

Op amp 210 is coupled to the supply terminals VDD and VSS. In this example, VDD may be used as a positive supply terminal, and VSS may be used as a negative or ground reference supply terminal. An output of op amp 210 controls the gate of the pass transistor Mpass. The transistor Mpass is a p-type metal oxide semiconductor (PMOS) device, and it has its source coupled to VDD and its drain coupled to the output terminal. The voltage at the output terminal is fed back through to the inverting input of op amp 210 through a voltage divider made up of R1 and R2. A designer may select values for R1 and R2 to achieve a desired gain. The non-inverting input of op amp 210 is coupled to VREF and to the auxiliary current path 220. In one example, VREF may be a voltage supplied to op amp 210 on a shared reference voltage line, such as illustrated in FIG. 1.

In some embodiments, as illustrated in FIG. 2, the op amp 210 includes a current mirror structure of transistors M4 and M7. Op amp 210 has transistors M4 and Mref making up one current path, and transistors M7 and Mfb making up a second current path. Transistors M4 and M7 are gate-coupled to each other, and in this example transistors M4 and M7 are PMOS devices. M4 and M7 have their sources coupled to VDD. The drain of transistor M4 is coupled to the gate of transistor Mpass. The drain of transistor M4 is coupled to the drain of transistor Mref, which is a n-type metal oxide semiconductor (NMOS) device. The drain of M7 is coupled to the drain of Mfb, which is configured as an NMOS device. The sources of Mref and Mfb are coupled together and are also coupled to the drain of transistor M8. Transistor M8 is an NMOS device, and it is configured to be used as a bias transistor to couple the sources of Mref and Mfb to VSS. The voltage at the gate of transistor Mfb is a feedback voltage (VFB).

The op amp 210 may also include multiple enable transistors. Transistor M5 is a PMOS device, coupled between VDD at its source and the drain of M4 at its drain. Transistor M6 is also a PMOS device. Transistor M6 has a source coupled to VDD and a drain coupled to the gate of transistor M7. Transistor M7 has a drain coupled to the gate of M7. The bias portion of the op amp 210 also includes enable transistor M9, which is an NMOS device. The drain of transistor M9 is coupled to the gate of transistor M8, and the source of transistor M9 is coupled to VSS.

The enable signals of FIG. 2 are shown as two different enable signals - enable (en) and enable bar (en˜). The signal enable bar has an opposite polarity to the enable signal, so that when the enable signal is high enable bar is low and vice versa.

Now looking to the auxiliary current path 220, it is coupled between VDD and VSS. Transistor M1 is an enable transistor, and it is configured as a PMOS device. The source of M1 is coupled to VDD, and the drain of M1 is coupled to the drain of Maux. The gate of transistor M1 is configured to receive the enable bar signal. Transistor M2 is an NMOS device that is configured as an enable transistor. The gate of transistor M2 is configured to receive the enable bar signal. M2 has a drain that is coupled to the source of transistor Maux and has a source that is coupled to VSS. Furthermore, the drain of M2 is coupled to a first terminal of capacitor C2, and the source of transistor M2 is coupled to a second terminal of capacitor C2.

The source of Maux is coupled to the drain of transistor M2 and to a first terminal of capacitor C1. The gate of Maux is coupled to a second terminal of capacitor C1.

The transistor Maux is configured as an NMOS device having a drain coupled to the drain of M1 and a source coupled to the drain of transistor M2. The gate of Maux is coupled to VREF and to the non-inverting input of op amp 210. Furthermore, the gate of Maux is coupled to the gate of Mref by virtue of both Maux and Mref being gate-coupled to the non-inverting terminal of the op amp 210.

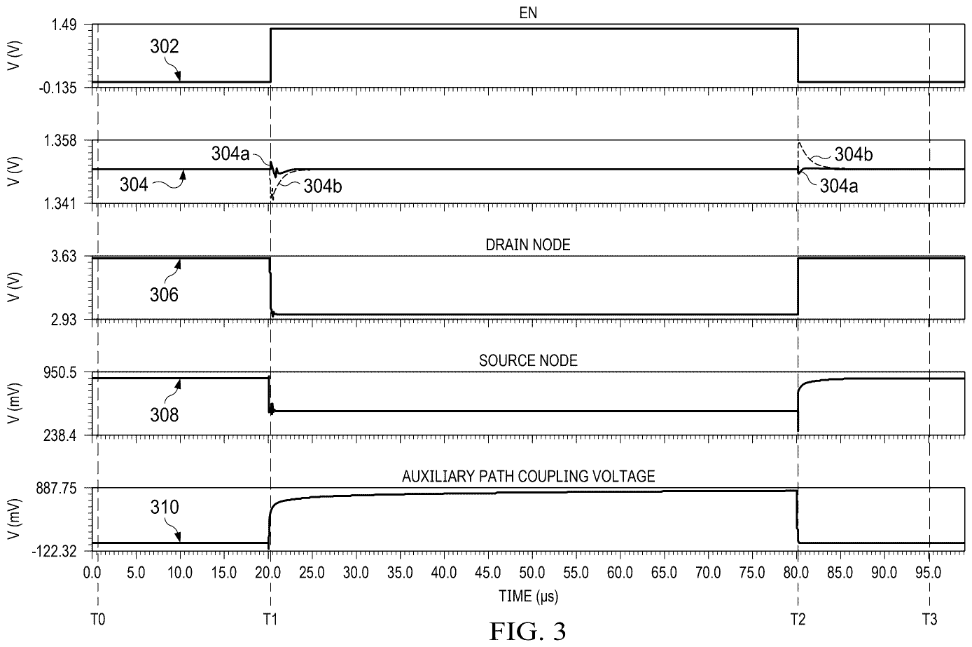

FIG. 3 is an illustration of voltages in the amplifier 200 of FIG. 2, according to some embodiments. The voltage 302 refers to the enable signal, and it is understood that enable bar is opposite in polarity at any given time. Voltage 304 refers to VREF. Voltage 304a refers to an aberration experienced by VREF during either enable or disable of the amplifier 200, where the amplifier 200 includes the auxiliary current path 220. Voltage 304b refers to an aberration experienced by VREF during either enable or disable of an amplifier, such as amplifier 200, where that amplifier does not include an auxiliary current path 200. Put another way, voltage 304b shows relatively large kickback on a shared reference voltage line, such as shared voltage line 115, attributable to the absence of an auxiliary current path.

Voltage 306 refers to the voltage at the drain of Mref, and voltage 308 refers to the voltage at the source of Mref. Voltage 310 refers to the voltage at the source of Maux and the drain of M2. This may also be referred to as the auxiliary path coupling voltage. Voltage 310 may be coupled to the gate of Maux through capacitor C1.

At time T0, the amplifier 200 is not enabled, as illustrated by the enable signal being low. Between time T0 and T1, the amplifier 200 is in the off state, and the output voltage and VFB are low. In this example, VREF is at a constant value, discounting the effects of the aberrations 304a and 304b, which means that Mref is on. When the enable signal 302 is low, that pulls the drain voltage of Mref to the supply level and also pulls the source voltage of Mref to the supply level. Furthermore, enable bar is high, which turns off transistor M1 and turns on transistor M2, thereby causing the source voltage of Maux to go low. Put another way, when transistor M1 is off and transistor M2 is on, that discharges capacitors C1 and C2 to VSS.

Also, when the enable signal 302 is low, that causes transistors M5 and M6 to turn on, thereby applying the voltage level VDD to the gate of the transistor Mpass and to the gates of transistors M4 and M7. Therefore, transistor Mpass is off, as are transistors M4 and M7. When the enable signal is low, and enable bar is high, that turns on transistor M9, thereby applying a low voltage to the gate of transistor M8 and turning transistor M8 off. The feedback voltage VFB is low, thereby turning transistor Mfb off.

Furthermore, there is a capacitive coupling between the gate and the drain of transistor Mref and capacitive coupling between the source and the drain of transistor Mref. The capacitive coupling is indicated as “Cgd coupling” and “Cgs coupling” in FIG. 2. At time T1, the enable signal goes high, which causes the voltages 306 and 308 to drop relatively quickly. For instance, voltage 306 may drop to a ground reference voltage, and voltage 308 may drop to VREF minus a threshold voltage of Mref. The change in voltage, with the capacitive coupling, may cause some aberration in the voltage 304. At time T1, enable bar is low, which turns on transistor M1 and turns off transistor M2. This results in a charge being capacitively coupled to the gate of Maux via capacitors C1 and C2. This is illustrated by voltage 310, which rises rapidly at time T1, eventually reaching a value of VREF minus the threshold voltage of Maux.

Thus, while capacitive coupling at transistor Mref includes a fast-changing drop in voltage at the gate of transistor Mref, there is simultaneously a fast-changing rise in voltage at the gate of transistor Maux. In the present embodiment, the transistors Mref and Maux may be selected so as to have a same threshold voltage, which may result in approximately equal and opposite voltage swings at the gates of transistors Mref and Maux.

In this manner, the voltage rise of the auxiliary path coupling voltage 310 compensates the voltage drop seen at the gate of Mref, thereby resulting in a relatively small aberration 304a, which immediately follows time T1. Without the compensation, the aberration would be expected to be larger, such as illustrated at aberration 304b immediately following time T1. The relatively large aberration 304b represents the kickback phenomenon discussed above.

With the enable signal high, the amplifier 200 is on. Transistors M5 and M6 turn off, as do transistors M4 and M7. Transistor M9 turns off, thereby allowing transistor M8 to turn on and with transistor M8 turned on, that exposes the sources of transistors Mref and Mfb to a low-voltage. Transistor Mref is on, by virtue of VREF, and that causes a low-voltage at the gate of Mpass, turning transistor Mpass on. The output voltage goes high, as does the feedback voltage VFB, which turns on transistor Mfb.

Between times T1 and T2, the amplifier 200 reaches stable operating points. At time T2, the enable signal goes low, which turns amplifier 200 off. Immediately preceding time T2, the auxiliary path coupling voltage 310 (at the source of Maux and the drain of M2) is at a steady value of VREF minus the threshold voltage of Maux. The auxiliary path coupling voltage 310 is capacitively coupled to the gate of Maux via capacitor C1. The drain and source voltages 306 and 308 of transistor Mref are low, and the voltages 306 and 308 are coupled to the gate of Mref by virtue of Cgd and Cgs. When the enable signal goes low at time T2, that causes the voltages 306 and 308 to rise rapidly, thereby affecting the non-inverting input terminal of op amp 210. However, when the enable signal goes high at time T2, that also discharges the auxiliary path coupling voltage 310 to VSS through transistor M2, thereby causing a rapid decrease in the auxiliary path coupling voltage 310, which is coupled to the non-inverting input terminal of op amp 210.

The rapid decrease of the auxiliary path coupling voltage 310 mostly cancels out the aberration caused by the rapid increase in the voltages 306 and 308, which are capacitively coupled to the non-inverting input. This is illustrated by the relatively small aberration 304A, immediately following time T2. In the absence of the compensation provided by the auxiliary current path 220, the aberration might be, such as illustrated by aberration 304b, immediately following time T2. The aberration 304b represents the kickback phenomenon described above.

At time T3, the enable signal is still low, and the various voltages 306-310 have reached a settled level during the off mode of the amplifier 200. The state of the voltages 302-310 is the same as the state of the voltages 302-310 at time T0. At an appropriate time, the enable signal may go high again, such as at time T1, thereby repeating the process described above.

One advantage of using auxiliary current path 220 in the amplifier 200 is that the auxiliary current path 220 may effectively and advantageously reduce or eliminate kickback and may use no active current. For instance, transistors M1 and M2 are controlled so that either one, but not both, may be on at a given time. Nevertheless, the auxiliary current path 220, the current path that includes transistors M4 and Mref, and the current path that includes transistors M7 and Mfb may be referred to as current paths because they couple a positive supply to a negative or ground supply via transistors. The current paths discussed above may use some amount of current when their respective transistors transition between on and off states, and that current may be negligible in some use cases.

In an example use case, the amplifier 200 may be used as a buffer, which may be employed as one of the components 111-112. In another example use case, the amplifier 200 may be used as an input amplifier for another component, such as component 110. Furthermore, multiple instances of the amplifier 200 may be implemented as input amplifiers for multiple components.

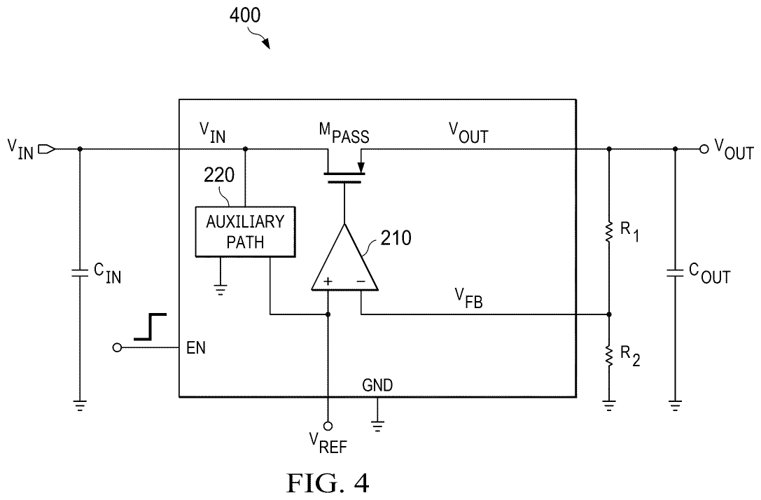

FIG. 4 is an illustration of example LDO voltage regulator 400, according to some embodiments. The LDO voltage regulator 400 may be implemented using the amplifier 200 of FIG. 2 as an input buffer. The input voltage Vin is applied to the drain of the transistor Mpass. The source of the transistor Mpass is used as the output voltage Vout. The Vin terminal is coupled to ground through an input capacitor Cin. The enable signal may be applied to the auxiliary current path 220 and the amplifier 210 as described above with respect to FIGS. 2 and 3. In this example, the auxiliary current path 220 is coupled between the Vin and ground supply terminals in the same way that the auxiliary current path 220 of FIG. 2 is coupled between the VDD and VSS supply terminals. Similarly, the transistors of the op amp 210 are coupled between the Vin and ground supply terminals in the same way that the transistors of the 210 are coupled between the VDD and VSS supply terminals in FIG. 2.

The values of the resistors R1 and R2 may be selected to provide an appropriate gain and a level for the feedback voltage VFB. The output voltage terminal Vout is coupled to ground via output capacitor Cout. The relationships between the auxiliary current path 220, the op amp 210, and the voltage VREF are the same as discussed above with respect to FIGS. 2-3. Specifically, the gates of the transistors Mref and Maux are both coupled to a shared reference voltage line at the noninverting input of op amp 210, which receives the reference voltage VREF. The reference voltage VREF may be received from an appropriate source, such as the bandgap voltage generator 102 of FIG. 1. The enable signal may be used to turn the LDO voltage regulator 400 and on and off in the same way that the amplifier 200 may be turned on and off by the enable signal, as described above with respect to FIGS. 2-3. The voltage output Vout is a regulated voltage, and its level is determined by the voltage divider that includes resistors R1 and R2.

Thus, in one example, the LDO voltage regulator 400 may be employed as one of the components 110-112 of FIG. 1. The LDO voltage regulator 400 may share a reference voltage line (e.g., provided as input to the non-inverting input of op-amp 210), such as shared reference voltage line 115 of FIG. 1. Since the LDO voltage regulator 400 includes the auxiliary current path 220 the amount of kickback may be, advantageously, relatively low, e.g., due to the compensation provided by the auxiliary current path 220. Since the kickback may be relatively low, transitions from an on state to an off state by LDO voltage regulator 400 may advantageously cause either no perceptible VREF aberrations or relatively small VREF aberrations, which may advantageously eliminate or minimize VREF interference with other components that share the reference voltage line.

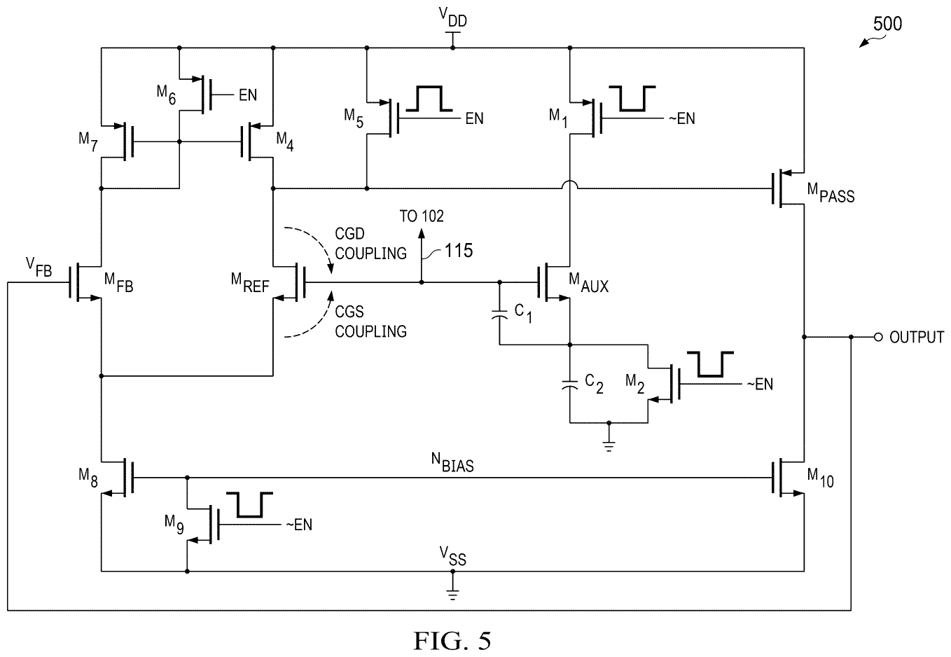

FIG. 5 is an illustration of an example amplifier 500, according to some embodiments. More specifically, amplifier 500 is similar in architecture and appearance to amplifier 200, but without illustrating the abstraction of op amp 210.

A difference between the architectures of amplifier 200 and amplifier 500 is that amplifier 500 includes an additional bias transistor M10. The bias transistor M10 has a drain that is coupled to a drain of Mpass and a source that is coupled to VSS. The gate of transistor M10 is coupled to the gate of transistor M8; therefore, transistors M8 and M10 are both coupled by their gates to the drain of transistor M9. The bias transistors M8 and M10 may also be referred to as pulldown transistors.

The output stage of the transistor includes Mpass and M10, where the output terminal is connected to the drain of Mpass and the drain of M10. The output terminal is coupled to the gate of Mfb, where the feedback voltage is referred to as VFB. Note in FIG. 5, that the feedback voltage VFB is not taken from a voltage divider, such as is illustrated in FIG. 2. In this example, the feedback voltage VFB causes the amplifier 500 to have unity gain, and the example of FIG. 2 indicates that any desired gain may be achieved by proper selection of resistors R1 and R2.

Furthermore, the example of FIG. 5 explicitly shows that the gate of transistor Mref may be shorted to the gate of transistor Maux and both gates are coupled to shared reference voltage terminal 115. The amplifier 500 may be implemented in various components 110-112 of FIG. 1, in a same or similar way as that described above with respect to amplifier 200 of FIG. 2.

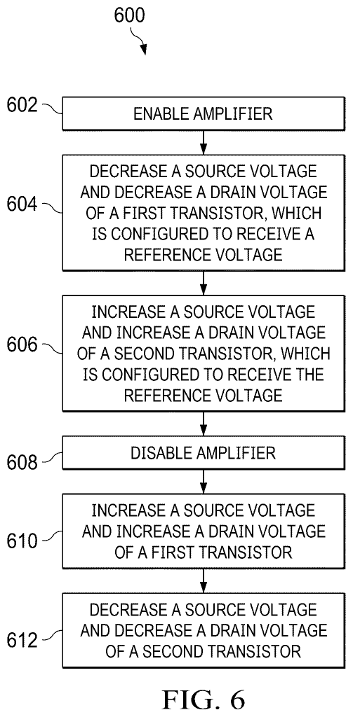

FIG. 6 is an illustration of an example method 600, according to some embodiments. Method 600 may be performed by an amplifier, such as the amplifier described above with respect to FIGS. 1-5.

At action 602, the amplifier starts in an off state (is disabled). Action 602 includes enabling the amplifier so that the amplifier transitions from the off state to an on state. Such transition is depicted in FIG. 3, where the enable signal (en 302) is low at time T0 and then goes to high at time T1. There is also a second enable signal, enable bar (en˜), which goes low when the enable signal goes high. When the enable signal transitions from low to high, and when the enable bar signal transitions from high to low, the enable signals are “asserted”, thereby causing the amplifier to attain the on state.

The enable signals may be received from any appropriate circuit, such as a control circuit. The second enable signal may be generated independently of the first enable signal, and in other implementations, the second enable signal may be generated from gating (e.g., by an inverter) the enable signal. In some embodiments, the enabling (action 602) and disabling (action 608) of the amplifier may be performed according to software or hardware logic.

At action 604, a source voltage of a first transistor is decreased, and a drain voltage of the first transistor is decreased. An example of the first transistor includes Mref, which is configured to receive the reference voltage VREF. When the amplifier is in an off state, the source and drain voltages of Mref settle to the positive supply voltage (e.g., VDD) or approximately the positive supply voltage. When the amplifier transitions to the on state, that causes the source and drain voltages of Mref to drop rapidly. As explained above, the source and drain are capacitively coupled to the gate of Mref, thereby causing a voltage drop aberration at the gate of Mref.

At action 606, a source voltage of a second transistor and a drain voltage of a second transistor are increased. An example of the second transistor includes Maux. When the amplifier is in an off state, the source and drain voltages of Maux are low, and when the amplifier transitions to the on state, that causes the source and drain voltages of Maux to increase rapidly.

Further in this example, the source terminal of the second transistor may be coupled to the gate terminal of the second transistor by a capacitor. The capacitor may be charged during the transition of the amplifier from the off state to the on state, thereby coupling a rapidly-rising charge to the gate of the second transistor. The gate of the first transistor is shorted to the gate of the second transistor so that the voltage drop caused by the capacitive coupling at the first transistor is compensated by the rapidly rising charge that is coupled to the gate and source of the second transistor. The compensation may result in a reduced or negligible amount of kickback, such as is illustrated in aberration 304a immediately following time T1 of FIG. 3.

The transition from action 606 to 608 illustrates that the amplifier may transition from an on state to an off state. The amplifier may also transition from the off state to the on state.

At action 608, the amplifier is disabled. The first enable signal may go high, and its complement enable bar may go low (the enable signals may be de-asserted), such as illustrated at time T2 in FIG. 3. This causes the amplifier to transition to the off (disabled) state.

While the amplifier is enabled, the source and drain voltages of the first transistor (e.g., Mref) are low, and during the transition to the disabled state at time T3, the source and drain voltages rapidly increase at action 610. The source and drain of the first transistor are capacitively coupled to the gate of the first transistor, so that the rapid increase in those voltages may cause an aberration in voltage at the gate of the first transistor. At action 612, the source and drain voltages at the second transistor (Maux) rapidly decrease. In the example of Maux, time T2 corresponds to discharging the capacitor C1, thereby rapidly reducing the charge at the gate of Maux. The gate of Maux is shorted to the gate of Mref, thereby compensating for the aberration voltage at the gate of Mref. The aberration may be illustrated by aberration 304a immediately following time T2 in FIG. 3.

Of course, the scope of implementations is not limited to only the series of actions shown in FIG. 6. Rather, various embodiments may add, omit, rearrange, or modify various ones of the actions. For instance, actions 602-606 may occur with each enable operation of the amplifier, and actions 608-612 may occur with each disable operation of the amplifier, and the amplifier may be enabled and disabled repeatedly as appropriate.

Example embodiments of the present disclosure are summarized here. Other embodiments can also be understood from the entirety of the specification and the claims filed herein.

Example 1. A circuit including: an amplifier having an enable input terminal configured to receive a first enable signal, and a first transistor having a current path coupled between first and second supply terminals, and a control terminal coupled to a reference terminal; a second transistor having a current path coupled between the first and second supply terminals, and a control terminal coupled to the reference terminal; a third transistor having a current path coupled between the control terminal of the second transistor and the second supply terminal, and a control terminal configured to receive a second enable signal; and a first capacitor coupled between the control terminal of the second transistor and the current path of the third transistor.

Example 2. The circuit of example 1, where the control terminal of the first transistor is shorted to the control terminal of the second transistor.

Example 3. The circuit of one of examples 1 or 2, where the second enable signal is an inverted version of the first enable signal.

Example 4. The circuit of one of examples 1 to 3, where the circuit is configured to: enable in response to an assertion of the first and second enable signals; and disable in response to a deassertion of the first and second enable signals.

Example 5. The circuit of one of examples 1 to 4, further including an output stage having an output terminal, where the circuit is configured to: produce a regulated voltage at the output terminal when the circuit is enabled; and disable the output stage when the circuit is disabled.

Example 6. The circuit of one of examples 1 to 5, where the reference terminal is configured to receive a reference signal, where the circuit is configured to produce the regulated voltage based on the reference signal.

Example 7. The circuit of one of examples 1 to 6, where the first capacitor is coupled between the control terminal of the second transistor and the current path of the second transistor.

Example 8. The circuit of one of examples 1 to 7, further including a second capacitor coupled between the first capacitor and the second supply terminal.

Example 9. The circuit of one of examples 1 to 8, where the amplifier includes: a differential input pair having the first transistor and a fourth transistor; and an output stage having an output terminal coupled to a control terminal of the fourth transistor.

Example 10. The circuit of one of examples 1 to 9, where the amplifier includes: a first current mirror coupled to the differential input pair; a fifth transistor having a current path coupled to the first current mirror, and a control terminal configured to receive the first enable signal; a bias transistor having a current path coupled between the differential input pair and the second supply terminal; and a sixth transistor having a current path coupled between a control terminal of the bias transistor and the second supply terminal, and a control terminal configured to receive the second enable signal.

Example 11. The circuit of one of examples 1 to 10, where the control terminal of the bias transistor is coupled to the output stage.

Example 12. The circuit of one of examples 1 to 11, where the first transistor and the second transistor are both N-type metal oxide semiconductor (NMOS) devices.

Example 13. The circuit of one of examples 1 to 12, where the first transistor and the second transistor have a same length dimension.

Example 14. The circuit of one of examples 1 to 13, where the first transistor and the second transistor have a same threshold voltage.

Example 15. The circuit of one of examples 1 to 14, where the amplifier is configured as a five pack amplifier having a first set of transistors arranged as a first current path, a second set of transistors arranged as a second current path, and a pulldown transistor coupling the first current path and the second current path to the second supply terminal, where the first transistor is disposed in the first current path, and where a feedback transistor is disposed in the second current path and has a control terminal coupled to an output of the amplifier.

Example 16. The circuit of one of examples 1 to 15, where the feedback transistor and the first transistor are both first N-type metal oxide semiconductor (NMOS) devices, where the first set of transistors includes a first P-type metal oxide semiconductor (PMOS) transistor coupled between the first supply terminal and the first transistor, and where the second set of transistors includes a second PMOS transistor coupled between the first supply terminal and the feedback transistor, where the first PMOS transistor and the second PMOS transistor are gate coupled to each other.

Example 17. The circuit of one of examples 1 to 16, further including: a third current path between the first supply terminal and the second supply terminal, where the third current path includes a pass transistor coupled between the first supply terminal and the output of the amplifier, where the control terminal of the feedback transistor is coupled to a current path terminal of the pass transistor.

Example 18. The circuit of one of examples 1 to 17, where the amplifier is included in a buffer having a gain of one with respect to the reference terminal.

Example 19. The circuit of one of examples 1 to 18, where the reference terminal is configured to receive a bandgap reference voltage.

Example 20. The circuit of one of examples 1 to 19, where the amplifier is configured as an operational amplifier having an inverting input and a non-inverting input, where the control terminal of the second transistor is coupled to the non-inverting input.

Example 21. The circuit of one of examples 1 to 20, where the circuit includes a low dropout (LDO) voltage regulator in which the operational amplifier is disposed, where a fourth transistor is arranged between an input voltage terminal and an output voltage terminal of the LDO voltage regulator, and where a control terminal of the fourth transistor is coupled to a current path terminal of the first transistor.

Example 22. The circuit of one of examples 1 to 21, where the first current path includes: a fourth transistor arranged between the second transistor and the first supply terminal; a fifth transistor, where the fifth transistor is arranged between the current path terminal of the second transistor and the second supply terminal, and where the fifth transistor is coupled in parallel with a second capacitor.

Example 23. The circuit of one of examples 1 to 22, where the first transistor, the second transistor, and the fifth transistor are N-type metal oxide semiconductor (NMOS) devices, and where the fourth transistor is a P-type metal oxide semiconductor (PMOS) device.

Example 24. An integrated circuit (IC) including: a bandgap reference circuit configured to generate a reference voltage at a reference voltage output; an amplifier having a reference input coupled to the reference voltage output and an inverting input coupled to a feedback path, where the amplifier further includes: a first current path having a first transistor having a current path disposed in series between first and second supply terminals, where a control terminal of the first transistor is coupled to the reference voltage output; a second current path having a second transistor having a current path disposed in series between the first and second supply terminals, where a control terminal of the second transistor is coupled to the reference voltage output and to the control terminal of the first transistor, and where the control terminal of the second transistor is coupled to the second supply terminal via a capacitor; and a third transistor having a current path coupled between the current path of the second transistor and the second supply terminal, and a control terminal configured to receive a first enable signal.

Example 25. The IC of example 24, further including: a first component, where the amplifier is implemented as an input amplifier of the first component; and a second component coupled to the reference voltage output, where the second component does not include an input amplifier.

Example 26. The IC of one of examples 24 or 25, where the first component includes a buffer, and where the second component includes an analog-to-digital converter (ADC).

Example 27. The IC of one of examples 24 to 26, where the first component includes a load dropout (LDO) voltage regulator, and where the second component includes an analog-to-digital converter (ADC).

Example 28. The IC of one of examples 24 to 27, further including: a first component, where the amplifier is implemented as an input amplifier of the first component; and a second component having an input amplifier, where the input amplifier of the second component includes: a third current path having a fourth transistor having a current path coupled in series between the first and second supply terminals, where a control terminal of the fourth transistor is coupled to the reference voltage output; and a fourth current path having a fifth transistor coupled in series between the first and second supply terminals, where a control terminal of the fifth transistor is coupled to the reference voltage output and to the control terminal of the fourth transistor, and where the control terminal of the fifth transistor is coupled to the second supply terminal via a second capacitor.

Example 29. The IC of one of examples 24 to 28, where the first component includes a buffer, and where the second component includes a low dropout (LDO) voltage regulator.

Example 30. The IC of one of examples 24 to 29, further including: an analog-to-digital converter (ADC) coupled to the reference voltage output, where the ADC does not include an input amplifier coupled to the reference voltage output.

Example 31. The IC of one of examples 24 to 30, where the amplifier further includes: a third current path arranged in parallel to the first current path, the third current path having a fourth transistor coupled between the first and second supply terminals, where a current path terminal of the fourth transistor is coupled to a current path terminal of the first transistor, and where a control terminal of the fourth transistor is coupled to an output of the amplifier.

Example 32. A method including: receiving a reference voltage with a control terminal of a first transistor of an amplifier, the first transistor having a current path coupled between first and second supply terminals; receiving the reference voltage with a control terminal of a second transistor of an auxiliary circuit, the second transistor having a current path coupled between the first and second supply terminals; receiving a first enable signal with a control terminal of a third transistor of the amplifier, the third transistor having a current path coupled to the current path of the first transistor; receiving a second enable signal with a control terminal of a fourth transistor of the auxiliary circuit, the fourth transistor having a current path coupled between the current path of the second transistor and the second supply terminal, where the second enable signal is an inverted version of the first enable signal; in response to an assertion of the first enable signal: causing a first source voltage at the first transistor to decrease; and causing a second source voltage at the second transistor to increase.

Example 33. The method of example 32, further including, in response to the assertion of the first enable signal: causing a first drain voltage at the first transistor to decrease; and causing a second drain voltage at the second transistor to increase.

Example 34. The method of one of examples 32 or 33, where causing the first drain voltage at the first transistor to decrease includes reducing the first drain voltage from a value of the first supply terminal, and where causing the first source voltage to decrease includes reducing the first source voltage from the value of the first supply terminal to a value of the reference voltage minus a threshold voltage of the first transistor.

Example 35. The method of one of examples 32 to 34, where causing the second drain voltage to increase includes increasing the second drain voltage from a value of the second supply terminal, and where causing the second source voltage to increase includes increasing the second source voltage from a value of the second supply terminal.

Example 36. The method of one of examples 32 to 35, where the current path of the first transistor is coupled to the second supply terminal via a fifth transistor, the method further including: charging a first capacitor that is coupled to the current path of the first and fourth transistors to a value of the reference voltage minus a threshold voltage of the third transistor in response to the first enable signal being asserted.

Example 37. The method of one of examples 32 to 36, where charging the first capacitor includes simultaneously turning on: a sixth transistor having a current path coupled to the current path of the second transistor; and the fourth transistor.

Example 38. The method of one of examples 32 to 37, further including: discharging a second capacitor that is coupled between the current path of the second transistor and the second supply terminal to a value of the second supply terminal in response to deasserting the first enable signal.

Example 39. The method of one of examples 32 to 38, where discharging the second capacitor includes: turning off a third transistor having a current path coupled to the current path of the second transistor; and turning on the fourth transistor.

Example 40. The method of one of examples 32 to 39, further including, in response to the first enable signal being deasserted: causing the first source voltage at the first transistor to increase; and causing the second source voltage at the second transistor to decrease.

Example 41. The method of one of examples 32 to 40, further including, in response to the first enable signal being deasserted: causing the first drain voltage at the first transistor to increase; and causing the second drain voltage at the second transistor to decrease.

Example 42. An integrated circuit (IC) includes a first circuit including: first and second supply terminals; an output terminal; a reference terminal; a first transistor having a current path coupled between the first and second supply terminals, and a control terminal coupled to the reference terminal; a second transistor having a current path coupled between the first and second supply terminals and a control terminal coupled to the reference terminal; a third transistor having a current path coupled between the current path of the second transistor and the second supply terminal; a first capacitor coupled between the control terminal of the second transistor and the current path of the third transistor; a second capacitor coupled between the first capacitor and the second supply terminal; a fourth transistor having a current path coupled between the current path of the first transistor and the second supply terminal; a fifth transistor having a current path coupled between the output terminal and the second supply terminal, and a control terminal coupled to a control terminal of the fourth transistor; a sixth transistor having a current path coupled between the first supply terminal and the output terminal, and a control terminal coupled to the current path of the first transistor; a seventh transistor having a current path coupled between the first supply terminal and the current path of the first transistor; an eighth transistor having a control terminal coupled to a control terminal of the seventh transistor; and a ninth transistor having a control terminal coupled to the output terminal, and a current path terminal coupled between a current path of the eighth transistor and a current path of the fourth transistor.

Example 43. The IC of example 42, where the first circuit further includes: a tenth transistor having a current path coupled between the first supply terminal and the current path of the second transistor; an eleventh transistor having a current path coupled between the first supply terminal and the control terminal of the sixth transistor; a twelfth transistor having a current path coupled between the first supply terminal and the control terminal of the eighth transistor; and a thirteenth transistor having a current path coupled between the control terminal of the fifth transistor and the second supply terminal.

Example 44. The IC of one of examples 42 or 43, where: the control terminal of the tenth transistor is configured to receive a first enable signal; the control terminal of the second transistor is configured to receive the first enable signal; the control terminal of the thirteenth transistor is configured to receive the first enable signal; the control terminal of the eleventh transistor is configured to receive a second enable signal, where the second enable signal is an inverted version of the first enable signal; and the control terminal of the eighth transistor is configured to receive a second enable signal.

Example 45. The IC of one of examples 42 to 44, further including: a bandgap circuit; and a linear voltage regulator including the first circuit, where the reference terminal of the first circuit is coupled to an output of the bandgap circuit.

Example 46. The IC of one of examples 42 to 45, further including an analog-to-digital converter (ADC) having an input coupled to the output of the bandgap circuit.

While various examples of the present disclosure have been described above, it should be understood that they have been presented by way of example only and not limitation. Numerous changes to the disclosed examples can be made in accordance with the disclosure herein without departing from the spirit or scope of the disclosure. Modifications are possible in the described embodiments, and other embodiments are possible, within the scope of the claims. Thus, the breadth and scope of the present invention should not be limited by any of the examples described above. Rather, the scope of the disclosure should be defined in accordance with the following claims and their equivalents.

What is claimed is:

1. A circuit comprising:
an amplifier having an enable input terminal configured to receive a first enable signal, and a first transistor having a current path coupled between first and second supply terminals, and a control terminal coupled to a reference terminal;
a second transistor having a current path coupled between the first and second supply terminals, and a control terminal coupled to the reference terminal;
a third transistor having a current path coupled between the control terminal of the second transistor and the second supply terminal, and a control terminal configured to receive a second enable signal; and
a first capacitor coupled between the control terminal of the second transistor and the current path of the third transistor.

2. The circuit of claim 1, wherein the control terminal of the first transistor is shorted to the control terminal of the second transistor.

3. The circuit of claim 1, wherein the second enable signal is an inverted version of the first enable signal.

4. The circuit of claim 1, wherein the circuit is configured to:
enable in response to an assertion of the first and second enable signals; and
disable in response to a deassertion of the first and second enable signals.

5. The circuit of claim 4, further comprising an output stage having an output terminal, wherein the circuit is configured to:
produce a regulated voltage at the output terminal when the circuit is enabled; and
disable the output stage when the circuit is disabled.

6. The circuit of claim 5, wherein the reference terminal is configured to receive a reference signal, wherein the circuit is configured to produce the regulated voltage based on the reference signal.

7. The circuit of claim 1, wherein the first capacitor is coupled between the control terminal of the second transistor and the current path of the second transistor.

8. The circuit of claim 1, further comprising a second capacitor coupled between the first capacitor and the second supply terminal.

9. The circuit of claim 1, wherein the amplifier comprises:
a differential input pair having the first transistor and a fourth transistor; and
an output stage having an output terminal coupled to a control terminal of the fourth transistor.

10. The circuit of claim 9, wherein the amplifier comprises:
a first current mirror coupled to the differential input pair;
a fifth transistor having a current path coupled to the first current mirror, and a control terminal configured to receive the first enable signal;
a bias transistor having a current path coupled between the differential input pair and the second supply terminal; and
a sixth transistor having a current path coupled between a control terminal of the bias transistor and the second supply terminal, and a control terminal configured to receive the second enable signal.

11. The circuit of claim 10, wherein the control terminal of the bias transistor is coupled to the output stage.

12. The circuit of claim 1, wherein the first transistor and the second transistor are both N-type metal oxide semiconductor (NMOS) devices.

13. The circuit of claim 1, wherein the first transistor and the second transistor have a same length dimension.

14. The circuit of claim 1, wherein the first transistor and the second transistor have a same threshold voltage.

15. The circuit of claim 1, wherein the amplifier is configured as a five pack amplifier having a first set of transistors arranged as a first current path, a second set of transistors arranged as a second current path, and a pulldown transistor coupling the first current path and the second current path to the second supply terminal, wherein the first transistor is disposed in the first current path, and wherein a feedback transistor is disposed in the second current path and has a control terminal coupled to an output of the amplifier.

16. The circuit of claim 15, wherein the feedback transistor and the first transistor are both first N-type metal oxide semiconductor (NMOS) devices, wherein the first set of transistors comprises a first P-type metal oxide semiconductor (PMOS) transistor coupled between the first supply terminal and the first transistor, and wherein the second set of transistors comprises a second PMOS transistor coupled between the first supply terminal and the feedback transistor, wherein the first PMOS transistor and the second PMOS transistor are gate coupled to each other.

17. The circuit of claim 15, further comprising:
a third current path between the first supply terminal and the second supply terminal, wherein the third current path includes a pass transistor coupled between the first supply terminal and the output of the amplifier, wherein the control terminal of the feedback transistor is coupled to a current path terminal of the pass transistor.

18. The circuit of claim 15, wherein the amplifier is included in a buffer having a gain of one with respect to the reference terminal.

19. The circuit of claim 1, wherein the reference terminal is configured to receive a bandgap reference voltage.

20. The circuit of claim 1, wherein the amplifier is configured as an operational amplifier having an inverting input and a non-inverting input, wherein the control terminal of the second transistor is coupled to the non-inverting input.

21. The circuit of claim 20, wherein the circuit comprises a low dropout (LDO) voltage regulator in which the operational amplifier is disposed, wherein a fourth transistor is arranged between an input voltage terminal and an output voltage terminal of the LDO voltage regulator, and wherein a control terminal of the fourth transistor is coupled to a current path terminal of the first transistor.

22. The circuit of claim 1, wherein the first current path comprises:
a fourth transistor arranged between the second transistor and the first supply terminal;
a fifth transistor, wherein the fifth transistor is arranged between the current path terminal of the second transistor and the second supply terminal, and wherein the fifth transistor is coupled in parallel with a second capacitor.

23. The circuit of claim 22, wherein the first transistor, the second transistor, and the fifth transistor are N-type metal oxide semiconductor (NMOS) devices, and wherein the fourth transistor is a P-type metal oxide semiconductor (PMOS) device.
